(19) United States
(12) Patent Application Publication
(10) Pub. No.: US 2008/0187826 A1
(43) Pub. Date: Aug. 7, 2008

(54) METHOD FOR EVALUATING BATTERY SAFETY UNDER INTERNAL SHORT-CIRCUIT CONDITION, BATTERY, BATTERY PACK, METHOD FOR PRODUCING BATTERY, AND METHOD FOR PRODUCING BATTERY PACK

(76) Inventors: Shinji KASAMATSU, Osaka (JP); Hajime NISHINO, Nara (JP); Masato FUJIKAWA, Osaka (JP); Mikinari SHIMADA, Osaka (JP)

Correspondence Address: MCDERMOTT WILL & EMERY LLP, 600 13TH STREET, NW, WASHINGTON, DC, 20005-3096, US

(21) Appl. No.: 12/027,105

(22) Filed: Feb. 6, 2008

(30) Foreign Application Priority Data
Feb. 6, 2007 (JP) 2007-026743

(51) Int. Cl. H01M 2/02; G01R 31/02

(52) U.S. Cl. 429/149; 429/163; 29/623.2; 324/500

(57) ABSTRACT

The invention relates to a method for evaluating the safety of a battery under an internal short-circuit condition. The battery includes an electrode assembly comprising a wound laminate of a positive electrode plate, a negative electrode plate, and a separator interposed between the positive and negative electrode plates. The positive electrode plate includes a positive electrode current collector and a positive electrode active material layer on the positive electrode current collector, and the negative electrode plate includes a negative electrode current collector and a negative electrode active material layer on the negative electrode current collector. The battery further includes an electrolyte and a casing for housing the electrode assembly and the electrolyte. The safety of the battery under an internal short-circuit condition is evaluated by causing a short-circuit only between the positive electrode active material layer of the positive electrode plate and the negative electrode plate inside the battery.

### FIELD OF THE INVENTION

The invention relates to a method for evaluating the safety of a battery under an internal short-circuit condition, a battery, a battery pack, and a method for producing the battery and the battery pack.

### BACKGROUND OF THE INVENTION

Lithium secondary batteries, which are lightweight and have high energy density, have been mainly used as the power source for portable devices. Also, lithium secondary batteries are currently receiving attention as large-sized, high-power power sources (e.g., power sources for automobiles), so they are being actively developed.

In lithium secondary batteries, a resin separator is disposed between a positive electrode plate and a negative electrode plate in order to electrically insulate the positive electrode plate and the negative electrode plate from each other and retain electrolyte. When lithium secondary batteries are stored in a very high temperature environment for an extended period of time, the separator may shrink to cause a contact between the positive electrode plate and the negative electrode plate, thereby resulting in an internal short-circuit.

To address such a problem, many attempts have been made to suppress internal short-circuits of batteries and enhance safety. For example, Japanese Laid-Open Patent Publication No. 2004-247064 proposes affixing insulating tape to the area of a positive or negative electrode plate where the current collector is exposed, in order to prevent an internal short-circuit between the current collectors. Japanese Laid-Open Patent Publication No. Hei 10-106530 proposes disposing an ion-conductive insulating layer composed of ceramic particles and a binder on an electrode plate.

Further, to check that safety is assured under an internal short-circuit condition, it is also very important to evaluate internal short-circuit safety. In UL standard for lithium batteries (UL1642) and Standard of Battery Association of Japan (SBA G1101-1997 guideline for safety evaluation standard for lithium secondary batteries), evaluation tests of exothermic behavior under an internal short-circuit condition are set forth as tests for evaluating the safety of batteries such as lithium secondary batteries. For example, a nail penetration test (e.g., Japanese Laid-Open Patent Publication No. Hei 11-102729) and a crush test are set forth.

A nail penetration test is conducted by sticking a nail into the side face of a battery to bring the positive electrode plate into electrical contact with the negative electrode plate through the nail inside the battery, thereby causing an internal short-circuit. A crush test is conducted by deforming a battery using a crushing member such as a round bar, square bar, or flat plate to bring the positive electrode plate into electrical contact with the negative electrode plate inside the battery, thereby causing an internal short-circuit. When the positive electrode plate and the negative electrode plate are brought into contact with each other, a short-circuit current flows through the contact area (short-circuited area) so that Joule's heat is generated. The safety of the battery is evaluated based on changes in battery temperature, battery voltage, etc., during the internal short-circuit.

The amount of heat W (W) generated upon an internal short-circuit is represented by the formula: W=V²×R1/(R1+R2)² where V represents the battery voltage (V), R1 represents the resistance (Ω) of the short-circuited area, and R2 represents the internal resistance (Ω) of the battery. This formula indicates that the amount of heat W changes with the resistance of the short-circuited area, and that as the resistance of the short-circuited area increases, the amount of heat increases. Therefore, in order to accurately evaluate the safety of a battery upon an internal short-circuit condition, it is important to cause a short-circuit in a high resistance area (area where a large amount of heat is produced) inside the battery.

In the case of nail penetration tests and crush tests, an internal short-circuit is caused near the surface of a battery (outermost part of an electrode assembly). Hence, if the outermost part of the electrode assembly has a low resistance area (e.g., an area where the current collector is exposed and no active material layer is formed), the battery is estimated to be highly safe based on an internal short-circuit in the low resistance area where a small amount of heat is generated. However, even in the aforementioned case where the outermost part of the electrode assembly has a low resistance area, if a foreign object enters the battery to cause a short-circuit between high resistance areas such as between the positive electrode active material layer and the negative electrode active material layer during the actual use of the battery, a greater amount of heat than in the above test may be produced.

As described above, in the case of conventional nail penetration tests and crush tests, the amount of heat generated upon an internal short-circuit is affected by the structure of the outermost part of an electrode assembly and the structure of a casing. It has been thus difficult to accurately evaluate safety under an internal short-circuit condition.

To solve the above-discussed prior art problems, an object of the invention is to provide a method capable of accurately and easily evaluating the safety of a battery under an internal short-circuit condition without being affected by the structure of the battery.

### BRIEF SUMMARY OF THE INVENTION

The invention is directed to a method for evaluating the safety of a battery under an internal short-circuit condition. The battery includes an electrode assembly comprising a wound laminate of a positive electrode plate, a negative electrode plate, and a separator interposed between the positive and negative electrode plates. The positive electrode plate includes a positive electrode current collector and a positive electrode active material layer on the positive electrode current collector, and the negative electrode plate includes a negative electrode current collector and a negative electrode active material layer on the negative electrode current collector. The battery further includes an electrolyte and a casing for housing the electrode assembly and the electrolyte. This safety evaluation method is characterized by causing a short-circuit only between the positive electrode active material layer of the positive electrode plate and the negative electrode plate.

According to the invention, it is possible to evaluate the safety of the battery under an internal short-circuit condition accurately and easily.

The invention also relates to a battery the safety of which is identified by the aforementioned safety evaluation method.

The invention further pertains to a battery pack including a plurality of the aforementioned batteries.

The battery of the invention is produced by the method including the successive steps of: (1) placing an electrode assembly in a casing, the electrode assembly comprising a wound laminate of a positive electrode plate, a negative electrode plate, and a separator interposed between the positive and negative electrode plates; (2) injecting an electrolyte into the casing; (3) sealing an opening of the casing with a sealing member to obtain a battery; (4) subjecting the battery to an initial charge and aging; and (5) identifying the safety of the battery under an internal short-circuit condition by the aforementioned safety evaluation method.

The invention further pertains to a method for producing a battery pack, including the step of placing a plurality of batteries obtained by the aforementioned production method in a package.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE SEVERAL VIEWS OF THE DRAWING

FIG. 1 is a longitudinal sectional view of a battery A in an Example of the invention;

FIG. 2 is a schematic perspective view, partially exploded, of the electrode assembly of the battery A illustrated in FIG. 1;

FIG. 3 is a schematic perspective view, partially exploded, of an electrode assembly subjected to a safety evaluation test in Example 1 of the invention; and

FIG. 4 is a schematic perspective view, partially exploded, of an electrode assembly subjected to a safety evaluation test in Example 8 of the invention.

### DETAILED DESCRIPTION OF THE INVENTION

The present inventors have diligently examined the effects of the structure of a battery and the location of a short-circuit inside the battery on the amount of heat generated by the battery upon the internal short-circuit. As a result, they have found that when a short-circuit is caused only between a positive electrode active material layer and a negative electrode plate, the largest amount of heat is generated by the battery, and that by causing such a short-circuit, the safety of a battery under an internal short-circuit condition can be accurately estimated.

In the case of nail penetration tests and crush tests, an internal short-circuit is caused near the surface of a battery (outermost part of the electrode assembly). Thus, if the outermost part of the electrode assembly has a low resistance area (e.g., an area where the current collector is exposed and no active material layer is formed), the safety is evaluated based on an internal short-circuit in the low resistance area. It should be noted that an internal short-circuit in a low resistance area generates less heat than an internal short-circuit in a high resistance area including a positive electrode active material layer since the short-circuit current is scattered. Also, when a short-circuit in a low resistance area and a short-circuit in a high resistance area occur at the same time, the short-circuit current tends to flow through the low resistance area, and most of the Joule's heat is generated in the low resistance area. Since most of the heat is generated in the low resistance area, the amount of heat generated is small. In this way, according to conventional methods, safety may be evaluated based on an internal short-circuit in a low resistance area, and safety cannot be accurately evaluated based on an internal short-circuit in a high resistance area.

Contrary to this, according to the invention, a short-circuit is caused only between a positive electrode active material layer with a low thermal stability and a negative electrode plate (at least one of a negative electrode active material layer and a negative electrode current collector), as described above. It is thus possible to reliably suppress the scattering of short-circuit current which occurs upon a short-circuit in a low resistance area. That is, reliable evaluation can be made based on a short-circuit only in a high resistance area where a large amount of heat is generated. Also, since the short-circuit current is not scattered, variations in the amount of heat generated by batteries are reduced. In this way, the invention can accurately evaluate the safety of a battery under an internal short-circuit condition, thereby enhancing the reliability of evaluation of internal short-circuit safety.

The battery evaluated by the method of the invention includes an electrode assembly comprising a wound laminate of a positive electrode plate, a negative electrode plate, and a separator interposed between the positive and negative electrode plates. The positive electrode plate includes a positive electrode current collector and a positive electrode active material layer on the positive electrode current collector, and the negative electrode plate includes a negative electrode current collector and a negative electrode active material layer on the negative electrode current collector. The battery further includes an electrolyte and a casing for housing the electrode assembly and the electrolyte. The battery satisfies one of the following conditions (1) to (4):

(1) the positive electrode plate has an area where the positive electrode current collector is exposed (the area where the current collector is exposed is hereinafter referred to as a “current-collector exposed area”) at an outermost part of the electrode assembly, and the casing is in the form of a can and electrically connected to the positive electrode plate (the casing serves as the positive electrode terminal);

(2) the positive electrode plate has a current-collector exposed area at an outermost part of the electrode assembly, and the casing is in the form of a can and electrically connected to the negative electrode plate (the casing serves as the negative electrode terminal);

(3) the positive electrode plate has a current-collector exposed area at an outermost part of the electrode assembly, and the casing is in the form of a can and electrically insulated from the positive electrode plate and the negative electrode plate; and

(4) the positive electrode plate does not have a current-collector exposed area at an outermost part of the electrode assembly (i.e., the positive electrode active material layer is formed on the whole surface of the positive electrode current collector), and the casing is in the form of a can and electrically connected to the positive electrode plate (the casing serves as the positive electrode terminal).

The electrode assembly is prepared by winding a laminate of the positive electrode plate, the negative electrode plate, and the separator. In winding the laminate, the part of the laminate positioned at the outermost part of the electrode assembly is grabbed at a strong pressure by using a jig. Hence, the positive and negative electrode plates at the outermost part are highly likely to be damaged by the jig. If the outermost part of the electrode assembly has the positive and negative electrode active material layers, the positive and negative electrode active materials are subject to separation. To suppress the damage of the electrode assembly due to such separation of the positive and negative electrode active materials, it is preferable not to form the positive electrode active material layer on the positive electrode current collector at the outermost part of the electrode assembly, so that the positive electrode plate has a current-collector exposed area at the outermost part thereof as in the above conditions (1) to (3). It is also preferable not to form the negative electrode active material layer on the negative electrode current collector at the outermost part of the electrode assembly, so that the negative electrode plate has a current-collector exposed area at the outermost part thereof.

The method for evaluating safety under an internal short-circuit condition according to the invention is directed to test methods in which a short-circuit is caused only between a positive electrode active material layer and a negative electrode plate and the amount of heat generated by the battery (the amount of increase in battery temperature) is measured. Examples of the test methods of the invention include (A) a nail penetration test, (B) a crush test, and (C) a test in which a foreign object is placed in a battery and the part of the battery containing the foreign object is pressed (hereinafter referred to as a “foreign object placement test”).

### (A) Nail Penetration Test

A nail is stuck into a battery to cause the nail to penetrate components such as the casing, thereby bringing the negative electrode plate into electrical contact with the positive electrode active material layer through the nail to cause an internal short-circuit. For example, the nail is stuck until it penetrates the negative electrode plate positioned at the outermost part of the electrode assembly and comes into contact with the positive electrode active material layer positioned at the outermost part of the electrode assembly.

One method for sticking the nail into the positive electrode active material layer is to check in advance the position of the positive electrode active material layer at the outermost part (the distance from the casing to the positive electrode active material layer) and stick the nail up to the position. Another method is to stick the nail, while monitoring the battery voltage, until the battery voltage drops to a predetermined value due to the occurrence of an internal short-circuit upon contact of the nail having penetrated the negative electrode plate with the positive electrode active material layer.

The material of the nail is, for example, a conductive metal material such as iron, aluminum, brass, copper, nickel, or stainless steel which is strong enough to stick into the battery.

When the positive electrode plate has a current-collector exposed area at the outermost part of the electrode assembly (the above conditions (1) to (3)), it is preferable to perform the aforementioned nail penetration test after removing at least the part of the current-collector exposed area of the positive electrode plate which the nail is to penetrate. In this case, it is possible to prevent an electrical contact between the negative electrode plate and the current-collector exposed area of the positive electrode plate through the nail and therefore scattering of short-circuit current.

The method of performing a nail penetration test after removing the current-collector exposed area of the positive electrode plate is specifically described below. A completed battery that has been subjected to such steps as an initial charge and aging is disassembled, and the electrode assembly is taken out of the battery. A part (outermost part) of the electrode assembly is unwound, and the current-collector exposed area of the positive electrode plate positioned at the outermost part of the electrode assembly is removed. The electrode assembly is then inserted into a casing, and the battery is sealed with sealing members such as a sealing plate and a gasket to prepare a test battery. Using the test battery, a nail penetration test is performed.

For the casing of the test battery, the casing used to assemble the battery may be used again, or an additionally prepared casing that is the same as that used to assemble the battery may be used. For the sealing members of the test battery such as the sealing plate and gasket, the ones used to assemble the battery may be used again, or additionally prepared sealing members that are the same as those used to assemble the battery may be used. Also, to make the operation easier, the positive electrode lead and the negative electrode lead connected to the electrode assembly may be removed. The test may be performed without sealing the battery by using the sealing members. This operation is preferably performed in a dry air atmosphere or an inert gas atmosphere such as nitrogen and argon, since there is a possibility that the positive electrode plate or the negative electrode plate may chemically react with moisture.

Methods for removing the current-collector exposed area of the positive electrode plate include cutting the current-collector exposed area from the positive electrode plate by using a cutting tool such as a cutter, making a hole in the current-collector exposed area by using an electric tool such as a drill, and chemically dissolving the current-collector exposed area by using hydrochloric acid, sulfuric acid, or the like. Among these methods, cutting the current-collector exposed area by using a cutter is preferable since the operation is easy.

Also, when the positive electrode plate has a current-collector exposed area at the outermost part of the electrode assembly (the above conditions (1) to (3)), it is preferable to perform the above nail penetration test after sticking a nail into the casing of the battery until it reaches the current-collector exposed area of the positive electrode plate and applying a current between the nail and the positive electrode plate to dissolve and remove the part of the current-collector exposed area of the positive electrode plate in contact with the nail in order to make a hole for nail passage.

This method is more specifically described below. An external power source is connected to the positive electrode plate (or positive electrode terminal) of the electrode assembly and a nail (e.g., the end of the nail opposite the pointed end for sticking), and a predetermined voltage is applied. Since the nail is insulated from the positive electrode plate, no current flows until the nail reaches the current-collector exposed area of the positive electrode plate. The nail is stuck until it reaches the current-collector exposed area of the positive electrode plate to cause a short-circuit so that the battery voltage drops to a predetermined value. With the stuck nail in contact with the current-collector exposed area of the positive electrode plate, a current is passed between the nail and the positive electrode plate (the contact area between the nail and the current-collector exposed area). The current flows between the current-collector exposed area of the positive electrode plate and the nail, so that the part of the positive electrode current collector in contact with the nail is heated to a temperature equal to or higher than the melting point due to Joule's heat. As a result, the part of the current-collector exposed area of the positive electrode plate in contact with the nail is melted and removed, so that a hole for nail passage is made. Thereafter, this nail is passed through the hole in the current-collector exposed area of the positive electrode plate, and further stuck until it reaches the positive electrode active material layer, in order to perform a nail penetration test. In this way, in the process of sticking a nail, a hole for nail passage can be easily made in the current-collector exposed area of the positive electrode plate without disassembling the battery.

The positive electrode current collector can be made of, for example, aluminum, an aluminum alloy, or stainless steel. The values of voltage and current set in the external power source can be determined as appropriate, depending on the material and thickness of the positive electrode current collector. For example, when the positive electrode current collector is 15 μm in thickness and composed simply of aluminum, the current value is approximately 30 to 60 A.

When the casing is electrically connected to the positive electrode plate and the positive electrode plate has the positive electrode active material layer at the outermost part of the electrode assembly (the above condition (4)), it is preferable to perform the above nail penetration test after electrically insulating the casing from the positive electrode plate.

More specifically, a battery is disassembled, and the electrode assembly is taken out of the casing. Then, the positive electrode lead electrically connecting the casing and the positive electrode plate is removed, and the positive electrode lead is cut from the casing or positive electrode plate. In this way, the electrical connection between the casing and the positive electrode plate through the positive electrode lead is cut off. Thereafter, the electrode assembly is inserted into a casing, and the battery is sealed with sealing members such as a sealing plate and a gasket to prepare a test battery. Using the test battery, a nail penetration test is performed.

In this case, it is possible to prevent a short-circuit between the casing and the negative electrode plate and therefore the scattering of short-circuit current. When the casing is electrically connected to the positive electrode plate, the casing serves as the positive electrode terminal. Since the casing serving as the positive electrode terminal can be made of aluminum metal, it can make the battery lighter than an iron casing serving as the negative electrode terminal.

Also, when the casing is electrically connected to the positive electrode plate and the positive electrode plate has the positive electrode active material layer at the outermost part of the electrode assembly (the above condition (4)), it is preferable to make a hole for nail passage in the casing, pass the nail through the hole, and perform the above nail penetration test.

In this case, it is possible to prevent a short-circuit between the casing and the negative electrode plate and therefore the scattering of short-circuit current. Since there is no need to disassemble the battery, the operation is easier than the aforementioned method of electrically insulating the casing from the positive electrode plate. Preferably, the area of the hole in the casing is sufficiently larger than the area of a cross-section of the nail perpendicular to the axial direction thereof.

Methods for making a hole in the casing include removing a part of the casing by using a tool such as a drill or cutter and chemically dissolving a part of the casing by using hydrochloric acid, sulfuric acid, or the like. Among them, making a hole by using a drill is preferable since the operation is easy.

### (B) Crush Test

A crushing member is pushed into a battery to deform the electrode plates inside the battery and cause a part of the electrode plates to penetrate the separator, thereby bringing the negative electrode plate in electrical contact with the positive electrode active material layer to cause an internal short-circuit. More specifically, the crushing member is pushed into the battery until the negative electrode plate positioned at the outermost part of the electrode assembly becomes deformed, partially penetrates the separator, and comes into contact with the positive electrode active material layer positioned at the outermost part of the electrode assembly.

One method for pushing the crushing member into the positive electrode active material layer is to check in advance the position of the positive electrode active material layer at the outermost part (the distance from the casing to the positive electrode active material layer) and push the crushing member up to the predetermined position. Another method is to push the crushing member, while monitoring the battery voltage, until the battery voltage drops to a predetermined value due to a contact (internal short-circuit) between the negative electrode plate and the positive electrode active material layer through the crushing member. The crushing member is, for example, a bar-like member such as a round or square bar made of iron which is strong enough to deform the battery (casing and electrode assembly).

When the positive electrode plate has a current-collector exposed area at the outermost part of the electrode assembly (the above conditions (1) to (3)), it is preferable to perform the above crush test after removing the current-collector exposed area of the positive electrode plate. In this case, in pushing the crushing member, it is possible to prevent an electrical contact between the negative electrode plate and the current-collector exposed area of the positive electrode plate and therefore scattering of short-circuit current. The current-collector exposed area of the positive electrode plate can be removed in the same manner as in the above nail penetration test.

When the casing is electrically connected to the positive electrode plate and the positive electrode plate has the positive electrode active material layer at the outermost part of the electrode assembly (the above condition (4)), it is preferable to perform the above crush test after electrically insulating the casing from the positive electrode plate. In this case, scattering of short-circuit current due to a short-circuit between the casing and the negative electrode plate is suppressed. The casing can be electrically insulated from the positive electrode plate in the same manner as in the above nail penetration test.

Also, when the casing is electrically connected to the positive electrode plate and the positive electrode plate has the positive electrode active material layer at the outermost part of the electrode assembly (the above condition (4)), it is preferable to make a hole for the passage of a crushing member in the casing, pass the crushing member through the hole, and perform the above crush test. In this case, it is possible to prevent a short-circuit between the casing and the negative electrode plate and therefore the scattering of short-circuit current. A hole can be made in the casing in the same manner as in the above nail penetration test.

### (C) Foreign Object Placement Test

A foreign object is placed between the positive electrode active material layer and the negative electrode plate in the electrode assembly. Thereafter, the part of the electrode assembly containing the foreign object is pressed with a pressing member to bring the negative electrode plate into electrical contact with the positive electrode active material layer through the foreign object, thereby causing an internal short-circuit. More specifically, the foreign object is placed in a part of the electrode assembly where the positive electrode active material layer and the negative electrode plate face each other (e.g., between the negative electrode plate and the separator) inside the battery. The part containing the foreign object is pressed with a pressing member to locally destroy the separator, thereby causing a contact between the positive electrode active material layer and the negative electrode plate through the foreign object to cause an internal short-circuit.

Since the foreign object can be placed at any desired location inside the battery, it is possible to select a location where a short-circuit is to be caused between the positive electrode active material layer and the negative electrode plate (the negative electrode active material layer or the current-collector exposed area of the negative electrode plate). The shape, material (hardness), and size of the foreign object, or the pressure applied to cause a short-circuit may be determined as appropriate, depending on the battery size, the strength and thickness of the electrode plates (active material layer and current collector), the strength and thickness of the separator, etc. The foreign object is, for example, a conductive member such as a piece of metal such as stainless steel which is strong enough to destroy the separator. The piece of metal preferably has a protrusion. By placing the piece of metal so as to protrude toward the separator along the pressing direction, the separator is readily destroyed. The pressing member is, for example, a dome-shaped member made of stainless steel.

When the positive electrode plate has a current-collector exposed area at the outermost part of the electrode assembly (the above conditions (1) to (3)), it is preferable to perform the above foreign object placement test after removing the current-collector exposed area of the positive electrode plate. In this case, in pushing the pressing member, it is possible to prevent an electrical contact between the negative electrode plate and the current-collector exposed area of the positive electrode plate and therefore scattering of short-circuit current. The current-collector exposed area of the positive electrode plate can be removed in the same manner as in the above nail penetration test.

The amount of heat generated by a battery upon an internal short-circuit (the amount of increase in battery temperature) can be measured, for example, using a thermocouple, thermoviewer, or calorimeter.

The invention also relates to a battery the safety of which is identified by the aforementioned safety evaluation method and a battery pack including a plurality of these batteries.

The battery of the invention can be produced, for example, by the following method. The method includes the successive steps of: (1) placing an electrode assembly in a casing, the electrode assembly comprising a wound laminate of a positive electrode plate, a negative electrode plate, and a separator interposed between the positive and negative electrode plates; (2) injecting an electrolyte into the casing; (3) sealing an opening of the casing with a sealing member to obtain a battery; (4) subjecting the battery to an initial charge and aging; and (5) identifying the safety of the battery under an internal short-circuit condition by the aforementioned safety evaluation method.

The battery pack of the invention can be prepared, for example, by placing a plurality of batteries the safety of which has been identified by the aforementioned method in a package.

As described above, according to the internal short-circuit safety evaluation method of the invention, it is possible to accurately evaluate the safety of a battery under an internal short-circuit condition and identify the safety level of the battery. Based on the identified safety level, it is possible to appropriately determine the use conditions of the battery and battery pack and design application devices. When the identified safety level of the battery is indicated on, for example, a battery catalogue, a label attached to the casing of the battery, or a label attached to the package of the battery pack, a battery user can easily identify the safety level of the battery. For example, the following indications are possible.

Battery A: “Internal short-circuit, 25° C.—nail penetration, 40° C.”

Battery B: “Internal short-circuit, 25° C.—nail penetration, 10° C.”

The indications on safety level are not limited to the above. For example, it is possible to use symbols and characters according to predetermined standards, in addition to numerical values showing test conditions and test results as described above.

The battery safety evaluation methods of the invention are preferably used as safety evaluation tests for, for example, primary batteries such as manganese dry batteries, alkaline dry batteries, and lithium primary batteries, and secondary batteries such as lead-acid batteries, nickel-cadmium storage batteries, nickel metal-hydride storage batteries, and lithium secondary batteries.

Examples of the invention are hereinafter described in detail. These Examples, however, are not to be construed as limiting in any way the invention.

### EXAMPLE 1

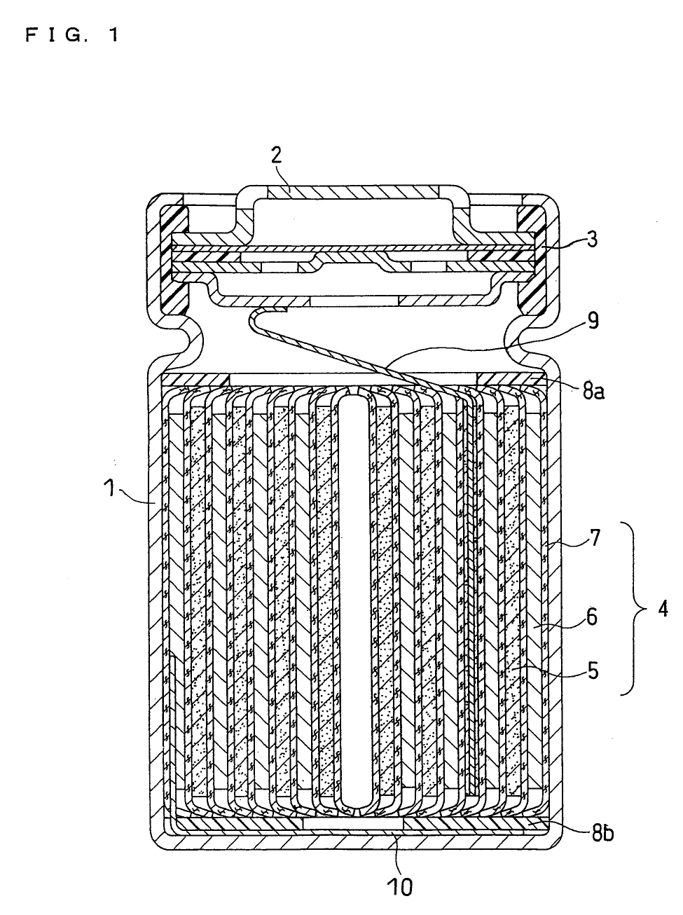

A cylindrical lithium secondary battery as illustrated in FIG. 1 was produced in the following manner as a battery to be subjected to a test using an internal short-circuit safety evaluation method of the invention.

### (1) Preparation of Positive Electrode Plate

A positive electrode mixture paste was prepared by mixing 3 kg of LiNi_{1/3}Mn_{1/3}Co_{1/3}O₂ powder with a median diameter of 15 μm (positive electrode active material), 1 kg of N-methyl-2-pyrrolidone (NMP) solution containing 12% by weight of polyvinylidene fluoride (PVDF) (binder) (#1320 (trade name) available from Kureha Corporation), 90 g of acetylene black powder (conductive material), and a suitable amount of NMP (dispersion medium). This positive electrode mixture paste was applied onto both faces of a long positive electrode current collector made of a 20-μm thick aluminum foil. The positive electrode mixture paste applied to the positive electrode current collector was dried to form a positive electrode active material layer on each side of the positive electrode current collector. This was then cut to obtain a long positive electrode plate 5 (width 56 mm). At this time, the positive electrode active material layers were rolled with reduction rolls to make the thickness of each positive electrode active material layer 180 μm.

In the preparation of the positive electrode plate, the positive electrode active material layer was not formed on an area of the positive electrode plate 5 to be positioned at the outermost part of the electrode assembly (which will be described later), in order to provide a current-collector exposed area 5b. Also, the positive electrode current collector was exposed at a central area of the positive electrode plate 5 in the longitudinal direction thereof to which an aluminum positive electrode lead 9 was to be welded. To this current-collector exposed area was welded the positive electrode lead 9, and the whole welded part of the positive electrode lead 9 on the current collector was covered with a polypropylene protective tape.

### (2) Preparation of Negative Electrode Plate

A negative electrode mixture paste was prepared by mixing 3 kg of artificial graphite powder with a median diameter of 20 μm (negative electrode active material), 75 g of an aqueous dispersion containing 40% by weight of modified styrene butadiene rubber particles (binder) (BM-400B (trade name) available from Zeon Corporation), 30 g of carboxymethyl cellulose (CMC) (thicker), and a suitable amount of water (dispersion medium). This negative electrode mixture paste was applied onto both faces of a long negative electrode current collector made of a 20-μm thick copper foil. The negative electrode mixture paste applied onto the negative electrode current collector was dried to form a negative electrode active material layer on each side of the negative electrode current collector. This was then cut to obtain a long negative electrode plate 6 (width 57.5 mm). At this time, the negative electrode active material layers were rolled with reduction rolls to make the thickness of each negative electrode active material layer 180 μm.

In the preparation of the negative electrode plate, the negative electrode active material layer was not formed on an area of the negative electrode plate 6 to be positioned at the outermost part of the electrode assembly (which will be described later), in order to provide a current-collector exposed area 6b. A nickel negative electrode lead 10 was welded to the end of the current-collector exposed area 6b opposite the negative electrode active material layer.

### (3) Assembly of Battery

An electrode assembly 4 was prepared by laminating the positive electrode plate 5 and the negative electrode plate 6 with a 20-μm thick polyethylene separator 7 (Hipore (trade name) available from Asahi Kasei Corporation) interposed therebetween and winding them.

A partially exploded perspective view of the electrode assembly 4 is shown in FIG. 2. In FIG. 2, the positive electrode active material layer 5a was not formed on the outermost part of the positive electrode plate 5, so that the current-collector exposed area 5b was provided. The negative electrode active material layer 6a was not formed on the outermost part of the negative electrode plate 6, so that the current-collector exposed area 6b was provided. Along the axial direction of the wound electrode assembly, the positive electrode lead 9 extends from one side of the electrode assembly (the opening side of the casing which will be described later), while the negative electrode lead 10 extends from the other side (the bottom side of the casing which will be described later).

The electrode assembly 4 was inserted into a cylindrical nickel-plated iron casing 1 with a bottom (diameter 18 mm, height 65 mm, internal diameter 17.85 mm) serving as the negative electrode terminal. At this time, an upper insulator plate 8a and a lower insulator plate 8b were fitted to the upper part and lower part of the electrode assembly 4, respectively. The end of the negative electrode lead 10 extending from the negative electrode plate 6 was welded to the inner bottom face of the casing 1, so that the negative electrode plate 6 was electrically connected to the negative electrode terminal through the negative electrode lead 10. Thereafter, 5.0 g of an electrolyte was injected into the casing 1. The electrolyte was prepared by dissolving LiPF₆ at a concentration of 1 mol/L in a solvent mixture of ethylene carbonate (EC), dimethyl carbonate (DMC), and ethyl methyl carbonate (EMC). The volume ratio of EC to DMC to EMC was 1:1:1. The electrolyte was then mixed with a 3% by weight of vinylene carbonate (VC).

The opening of the casing 1 was sealed with a cover serving as the positive electrode terminal. More specifically, the battery was sealed by crimping the open edge of the casing 1 onto the circumference of a sealing plate 2 serving as the positive electrode terminal with a gasket 3 interposed therebetween. At this time, the edge of the positive electrode lead 9 extending from the positive electrode plate 5 was welded to the sealing plate 2, so that the positive electrode plate 5 was electrically connected to the positive electrode terminal through the positive electrode lead 9. In this way, a lithium secondary battery with a capacity of 2400 mAh was produced.

The battery was subjected to an initial charge and aging in the following conditions immediately after the production of the battery.

The battery was charged/discharged at a constant current of 400 mA twice and then charged at the constant current of 400 mA until the closed circuit voltage reached 4.1 V. Thereafter, the battery was stored in a 45° C. environment for 7 days. After the storage, the battery was charged at a constant current of 1500 mA until the battery voltage reached 4.25 V. After 4.25 V was reached, the battery was charged at the constant voltage of 4.25 V until the current value reached 100 mA. This battery was designated as a battery A and subjected to a test for evaluating the safety under an internal short-circuit condition in the following manner.

### (4) Internal Short-Circuit Safety Evaluation Test (Nail Penetration Test)

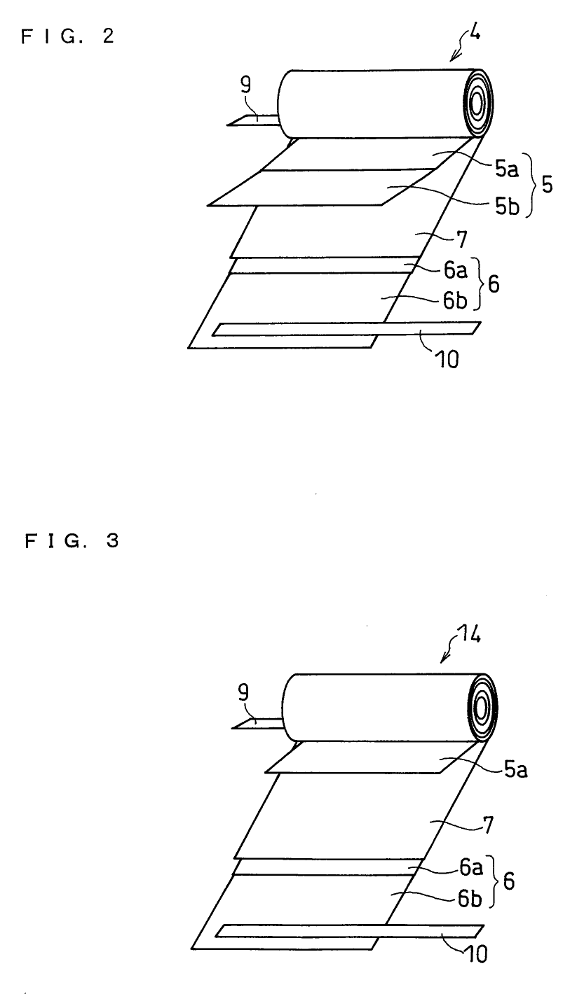

The battery was disassembled in a dry atmosphere, and the electrode assembly was taken out of the casing. As illustrated in FIG. 2, a part (outermost part) of the electrode assembly was unwound. At this time, the positive electrode lead and the negative electrode lead were removed from the battery. The current-collector exposed area 5b of the positive electrode plate positioned at the outermost part thereof was cut with a cutter. The state of the electrode assembly after the cutting is illustrated in FIG. 3. Thereafter, the electrode assembly was rewound and inserted into an additionally prepared casing which was the same as the above one.

The battery was placed in a 25° C. constant temperature oven to make the battery temperature 25° C. A 3-mm diameter iron nail was stuck into the battery to internally short-circuit the battery. More specifically, the nail was stuck into the battery at a constant speed of 1 mm/s until the nail penetrated the negative electrode plate (negative electrode current collector and negative electrode active material layer) and came into contact with the positive electrode active material layer of the positive electrode plate positioned at the outermost part of the electrode assembly, thereby causing an internal short-circuit so that the battery voltage dropped to 4.0 V or less. In this way, an internal short-circuit was caused only between the negative electrode plate and the positive electrode active material layer inside the battery. At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

After the test, the batteries were disassembled and examined, and it was found that the pores of the separator were closed around the nail penetration site at the outermost part of the electrode assembly (between the positive electrode active material layer and the current-collector exposed area of the negative electrode plate at the outermost part of the electrode assembly). It should be noted that this phenomenon of closing of the pores of a separator occurs in a short-circuited area due to melting of the separator by heat.

### EXAMPLE 2

Using the same battery A as that in Example 1, an internal short-circuit safety evaluation (nail penetration test) was performed in the following manner.

A nail was stuck into the battery at a constant speed of 1 mm/s until the nail came into contact with the current-collector exposed area of the positive electrode plate positioned at the outermost part of the electrode assembly, thereby causing an internal short-circuit so that the battery voltage dropped to 4.0 V or less.

A direct-current power source (EX1500LS available from Takasago Ltd.) was connected to the nail and the positive electrode plate as an external power source. Thereafter, a current was passed between the nail and the positive electrode plate to melt and remove the part of the current-collector exposed area of the positive electrode plate in contact with the nail, in order to make a hole for nail passage. At this time, the power source was set such that the maximum voltage was 5 V and the maximum current was 60 A. When the current value dropped to 1 A or less, it was determined that the part of the current-collector exposed area of the positive electrode plate in contact with the nail was removed and a hole was made.

The battery was placed in a 25° C. constant temperature oven to make the battery temperature 25° C. Further, the nail was stuck into the battery to a depth of 3 mm to internally short-circuit the battery. Specifically, the nail was stuck into the battery at a constant speed of 1 mm/s until the nail passed through the hole and came into contact with the positive electrode active material layer of the positive electrode plate at the outermost part of the electrode assembly, thereby causing an internal short-circuit so that the battery voltage dropped to 4.0 V or less. In this way, an internal short-circuit was caused only between the negative electrode plate (negative electrode current collector and negative electrode active material layer) and the positive electrode active material layer inside the battery.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 3

A battery B was produced in the same manner as in Example 1 except for the following. In preparing the positive electrode plate, the positive electrode active material layer was formed on an area of the positive electrode plate positioned at the outermost part of the electrode assembly, so that the current-collector exposed area was not provided. In assembling the battery, the electrode assembly was inserted into the cylindrical aluminum casing with the bottom, and the end of the positive electrode lead connected to the positive electrode plate was welded to the casing. The end of the negative electrode lead connected to the negative electrode plate was welded to a metal sealing member.

The battery B was subjected to an internal short-circuit safety evaluation test (nail penetration test) in the following manner. The battery B was disassembled in a dry atmosphere, and the electrode assembly was taken out of the casing. Then, the casing was electrically insulated from the positive electrode plate. Specifically, the part of the positive electrode lead welded to the casing was removed. Thereafter, the electrode assembly was inserted into an additionally prepared casing which was the same as the above one.

The battery was placed in a 25° C. constant temperature oven to make the battery temperature 25° C. A 3-mm diameter iron nail was stuck into the battery to internally short-circuit the battery. More specifically, the nail was stuck into the battery at a constant speed of 1 mm/s until the nail came into contact with the positive electrode active material layer of the positive electrode plate positioned at the outermost part of the electrode assembly, thereby causing an internal short-circuit so that the battery voltage dropped to 4.0 V or less. In this way, an internal short-circuit was caused only between the negative electrode plate (the current collector exposed area) and the positive electrode active material layer inside the battery.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 4

Using the same battery B as that in Example 3, an internal short-circuit safety evaluation test (nail penetration test) was performed in the following manner.

The battery was placed on a drilling machine and a hole for nail passage was made in the casing, using a drill (diameter 7 mm and the point angle 118°). Due to the rotation of the drill, the drill cuttings of the casing were blown out.

The battery was placed in a 25° C. constant temperature oven to make the battery temperature 25° C. A 3-mm diameter iron nail was stuck into the battery to internally short-circuit the battery. Specifically, the nail was stuck into the electrode assembly through the hole in the casing at a constant speed of 1 mm/s until the nail came into contact with the positive electrode active material layer of the positive electrode plate positioned at the outermost part of the electrode assembly, thereby causing an internal short-circuit so that the battery voltage dropped to 4.0 V or less. In this way, an internal short-circuit was caused only between the negative electrode plate (the current collector exposed area) and the positive electrode active material layer inside the battery.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 5

Using the same battery A as that in Example 1, an internal short-circuit safety evaluation test (crush test) was performed in the following manner.

The battery was disassembled in a dry atmosphere, and the electrode assembly was taken out of the casing. As illustrated in FIG. 2, a part (outermost part) of the electrode assembly was unwound. The current-collector exposed area 5b of the positive electrode plate positioned at the outermost part thereof was cut with a cutter. The state of the electrode assembly after the cutting is illustrated in FIG. 3. Thereafter, the electrode assembly was rewound and inserted into an additionally prepared casing which was the same as the above one.

The battery was placed in a 25° C. constant temperature oven to make the battery temperature 25° C. A 6-mm diameter iron crushing member in the shape of a round bar was pushed into the battery to internally short-circuit the battery. Specifically, the crushing member was pushed into the battery at a constant speed of 1 mm/s until the crushing member deformed the battery to bring the current-collector exposed area of the negative electrode plate positioned at the outermost part of the electrode assembly into contact with the positive electrode active material layer of the positive electrode plate positioned at the outermost part of the electrode assembly so that the battery voltage dropped to 4.0 V or less. In this way, an internal short-circuit was caused only between the negative electrode plate (negative electrode active material layer) and the positive electrode active material layer inside the battery.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 6

Using the same battery B as that in Example 3, an internal short-circuit safety evaluation test (crush test) was performed in the following manner.

The battery B was disassembled in a dry atmosphere, and the electrode assembly was taken out of the casing. Then, the casing was electrically insulated from the positive electrode plate. Specifically, the part of the positive electrode lead welded to the casing was removed. Thereafter, the electrode assembly was inserted into an additionally prepared casing which was the same as the above one.

The battery was placed in a 25° C. constant temperature oven to make the battery temperature 25° C. A 6-mm diameter iron crushing member in the shape of a round bar was pushed into the battery to internally short-circuit the battery. More specifically, the crushing member was pushed into the battery at a constant speed of 1 mm/s until the crushing member deformed the battery to bring the current-collector exposed area of the negative electrode plate positioned at the outermost part of the electrode assembly into contact with the positive electrode active material layer of the positive electrode plate positioned at the outermost part of the electrode assembly so that the battery voltage dropped to 4.0 V or less. In this way, an internal short-circuit was caused only between the negative electrode plate (the current collector exposed area) and the positive electrode active material layer.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 7

Using the same battery B as that in Example 3, an internal short-circuit safety evaluation test (crush test) was performed in the following manner.

The battery was placed on a drilling machine, and a hole for the passage of a crushing member was made in the casing, using a drill (diameter 7 mm and the angle of the pointed end 118°). Due to the rotation of the drill, the drill cuttings of the casing were blown out.

The battery was placed in a 25° C. constant temperature oven to make the battery temperature 25° C. A 6-mm diameter iron crushing member in the shape of a round bar was pushed into the battery to internally short-circuit the battery. More specifically, the crushing member was pushed into the battery at a constant speed of 1 mm/s until the crushing member deformed the battery to bring the current-collector exposed area of the negative electrode plate positioned at the outermost part of the electrode assembly into contact with the positive electrode active material layer of the positive electrode plate positioned at the outermost part of the electrode assembly so that the battery voltage dropped to 4.0 V or less. In this way, an internal short-circuit was caused only between the negative electrode plate (the current collector exposed area) and the positive electrode active material layer.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### EXAMPLE 8

Using the same battery A as that in Example 1, an internal short-circuit safety evaluation test (foreign object placement test) was performed in the following manner.

The battery was disassembled in a dry atmosphere, and the electrode assembly was taken out of the casing. As illustrated in FIG. 2, a part (outermost part) of the electrode assembly was unwound. The current-collector exposed area 5b of the positive electrode plate positioned at the outermost part thereof was cut with a cutter. The electrode assembly 14 after the cutting is illustrated in FIG. 3.

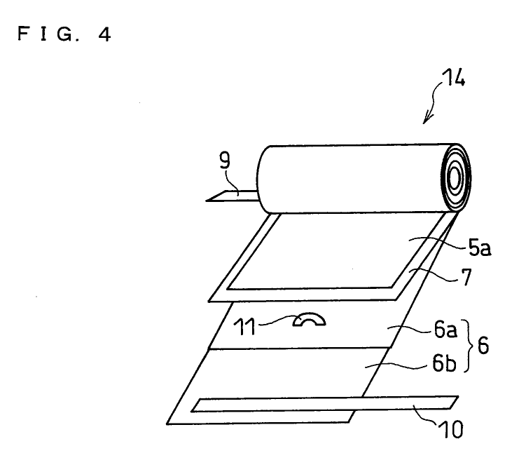

As illustrated in FIG. 4, a stainless steel plate 11 in the shape of a horseshoe (width 200 μm, thickness 300 μm, height 3 mm) was placed between the negative electrode plate 6 and the separator 7 in the area of the electrode assembly 14 where the positive electrode active material layer 5a and the negative electrode active material layer 6a faced each other. More specifically, the plate 11 was disposed on the negative electrode plate 6 so that the thickness direction of the plate 11 was perpendicular to the thickness direction of the negative electrode plate 6. Thereafter, the electrode assembly was rewound and inserted into an additionally prepared casing which was the same as the above one. The battery was sealed with additionally prepared sealing plate and gasket which were the same as the above ones.

The battery was placed in a 60° C. constant temperature oven to make the battery temperature 60° C. Thereafter, using a dome-shaped stainless steel pressing member of 6 mm in diameter, the battery was pressed to internally short-circuit the battery. More specifically, the battery was pressed with the pressing member at a pressing speed of 1 mm/s and a maximum pressure of 50 kg/cm² until the plate penetrated the separator to cause a contact between the negative electrode active material layer and the positive electrode active material layer via the plate so that the battery voltage dropped to 4.0 V or less. In this way, an internal short-circuit was caused only between the negative electrode plate (the negative electrode active material layer) and the positive electrode active material layer inside the battery.

At this time, the temperature of the battery surface was measured with a thermocouple, and the amount of increase in battery temperature in 5 seconds following the occurrence of the internal short-circuit was obtained. Using 10 test batteries, the average value and standard deviation of the amount of increase in battery temperature were determined.

### COMPARATIVE EXAMPLE 1

An internal short-circuit safety evaluation test (nail penetration test) was performed in the same manner as in Example 1, except that the current-collector exposed area of the positive electrode plate was not cut.

After the test, the batteries were disassembled and examined, and it was found that the pores of the separator between the current-collector exposed area of the positive electrode plate and the negative electrode plate at the outermost part were closed. It should be noted that this phenomenon of closing of the pores of a separator occurs near a short-circuited area, and the result indicates that a short-circuit occurred other than between the positive electrode active material layer and the negative electrode plate.

### COMPARATIVE EXAMPLE 2

An internal short-circuit safety evaluation test (nail penetration test) was performed in the same manner as in Example 3, except that the step of disassembling the battery B and electrically insulating the casing from the positive electrode plate was not performed.

### COMPARATIVE EXAMPLE 3

An internal short-circuit safety evaluation test (crush test) was performed in the same manner as in Example 5, except that the current-collector exposed area of the positive electrode plate was not cut.

### COMPARATIVE EXAMPLE 4

An internal short-circuit safety evaluation test (crush test) was performed in the same manner as in Example 6, except that the step of disassembling the battery B and electrically insulating the casing from the positive electrode plate was not performed.

### COMPARATIVE EXAMPLE 5

An internal short-circuit safety evaluation test was performed in the same manner as in Example 8, except that the current-collector exposed area of the positive electrode plate was not cut.

The evaluation results of Examples 1 to 8 and Comparative Examples 1 to 5 are shown in Table 1.

TABLE 1

| | | | Amount of increase in | |
|---|---|---|---|---|
| | | | battery temperature upon | |
| | | | internal short-circuit | |
| | | How short-circuit was | Average | Standard |
| | Method | caused | value (° C.) | deviation |
| Example 1 | The current-collector exposed area of | Nail penetration | 40 | 1.6 |
| | the positive electrode plate was cut. | | | |
| Example 2 | A hole was made in the current- | Nail penetration | 43 | 1.5 |
| | collector exposed area of the | | | |
| | positive electrode plate. | | | |
| Example 3 | The casing was insulated. | Nail penetration | 45 | 1.7 |
| Example 4 | A hole was made in the casing. | Nail penetration | 42 | 1.6 |
| Example 5 | The current-collector exposed area of | Crush | 35 | 2 |
| | the positive electrode plate was cut. | | | |
| Example 6 | The casing was insulated. | Crush | 38 | 2.2 |
| Example 7 | A hole was made in the casing. | Crush | 39 | 2.3 |
| Example 8 | The current-collector exposed area of | Foreign object | 36 | 2 |
| | the positive electrode plate was cut. | placement | | |
| Comparative | — | Nail penetration | 12 | 3.5 |
| Example 1 | | | | |
| Comparative | — | Nail penetration | 14 | 4.5 |
| Example 2 | | | | |
| Comparative | — | Crush | 15 | 5.2 |
| Example 3 | | | | |
| Comparative | — | Crush | 13 | 5.5 |
| Example 4 | | | | |
| Comparative | — | Foreign object | 18 | 3.2 |
| Example 5 | | placement | | |

According to the methods of Examples 1 to 4, the amount of increase in battery temperature upon the internal short-circuit was 35 to 45° C., and there were small variations in the amount of increase in battery temperature among the batteries. Contrary to this, according to the methods of Comparative Examples 1 and 2, a short-circuit occurred between low resistance areas (between the current-collector exposed area of the positive electrode plate and the current-collector exposed area of the negative electrode plate, or between the casing connected to the positive electrode plate and the negative electrode plate) so that the short-circuit current was scattered. Thus, the amount of increase in battery temperature upon the internal short-circuit was small, and there were large variations in the amount of increase in battery temperature among the batteries. Also, in the case of the crush tests in Examples 5 to 7 of the invention and Comparative Examples 3 to 4 and the foreign object placement tests in Example 8 of the invention and Comparative Example 5, the same tendency as in the nail penetration tests was found.

### EXAMPLE 9

After the negative electrode active material layers were formed in the same manner as in Example 1, a heat-resistant insulating porous film (hereinafter simply a “porous film”) was formed on the surface of each of the negative electrode active material layers.

A paste was prepared by mixing 970 g of alumina with a median diameter of 0.3 μm (insulating filler), 375 g of NMP solution containing 8% by weight of modified polyacrylonitrile rubber (binder) (BM-720H available from Zeon Corporation), and a suitable amount of NMP. This paste was applied onto the surface of each negative electrode active material layer and vacuum dried at 120° C. for 10 hours to form a 0.5-μm thick porous film on the negative electrode active material layer. In this way, a negative electrode plate B was prepared. The porosity of the porous film was 48%. The porosity was calculated from the thickness of the porous film determined by using an SEM photo of a cross-section of the negative electrode plate, the amount of alumina in the porous film per unit area determined by fluorescent X-ray analysis, the true specific gravities of alumina and the binder, and the weight ratio of alumina to the binder.

Except for the above-described formation of the porous film on the surface of the negative electrode active material layer, a battery A2 was produced in the same manner as in Example 1. The battery A2 was subjected to an internal short-circuit safety evaluation test in the same manner as in Example 1.

As a result, the average value of battery temperature increases was 10° C. In the same manner as in Example 1, the safety of the battery upon the internal short-circuit could be accurately evaluated and the safety level of the battery could be identified. Since the battery A2 had the porous film on the surface of the negative electrode plate, the internal short-circuit safety of the battery A2 improved. Even in the event of an internal short-circuit, the short-circuited spot promptly disappeared due to the presence of the porous film, so that the insulation was restored. As a result, the amount of Joule's heat generated in the short-circuit spot significantly decreased and the battery safety significantly improved.

Although the invention has been described in terms of the presently preferred embodiments, it is to be understood that such disclosure is not to be interpreted as limiting. Various alterations and modifications will no doubt become apparent to those skilled in the art to which the invention pertains, after having read the above disclosure. Accordingly, it is intended that the appended claims be interpreted as covering all alterations and modifications as fall within the true spirit and scope of the invention.

1. A method for evaluating the safety of a battery under an internal short-circuit condition,
said battery comprising:
an electrode assembly comprising a wound laminate of a positive electrode plate, a negative electrode plate, and a separator interposed between said positive and negative electrode plates, said positive electrode plate including a positive electrode current collector and a positive electrode active material layer on said positive electrode current collector, said negative electrode plate including a negative electrode current collector and a negative electrode active material layer on said negative electrode current collector;
an electrolyte; and
a casing for housing said electrode assembly and said electrolyte,
said method comprising the step of causing a short-circuit only between said positive electrode active material layer of said positive electrode plate and said negative electrode plate.

2. The method for evaluating the safety of a battery under an internal short-circuit condition in accordance with claim 1, wherein a nail is stuck into said battery to bring said negative electrode plate into electrical contact with said positive electrode active material layer through said nail.

3. The method for evaluating the safety of a battery under an internal short-circuit condition in accordance with claim 2,
wherein said casing is electrically connected to said negative electrode plate,
the electrode on the outermost side of said electrode assembly is said negative electrode plate,
said positive electrode plate has an area where said positive electrode current collector is exposed at an outermost part of said electrode assembly, and
said method includes the steps of: removing said area where said positive electrode current collector is exposed; and sticking said nail into the casing of said battery until it reaches the positive electrode active material layer positioned at the outermost part of said electrode assembly in said positive electrode plate.

4. The method for evaluating the safety of a battery under an internal short-circuit condition in accordance with claim 2,
wherein said casing is electrically connected to said negative electrode plate,
the electrode on the outermost side of said electrode assembly is said negative electrode plate,
said positive electrode plate has an area where said positive electrode current collector is exposed at an outermost part of the electrode assembly, and
said method includes the steps of: sticking said nail into the casing of said battery until it reaches said area where said positive electrode current collector is exposed; applying a current to said nail and said area where said positive electrode current collector is exposed to melt and remove the part of said positive electrode current collector in contact with said nail in order to make a hole; and passing said nail through said hole and further sticking said nail until it reaches the positive electrode active material layer positioned at the outermost part of said electrode assembly in said positive electrode plate.

5. The method for evaluating the safety of a battery under an internal short-circuit condition in accordance with claim 2,
wherein said casing is electrically connected to said positive electrode plate,
the electrode on the outermost side of said electrode assembly is said negative electrode plate,
said positive electrode plate has said positive electrode active material layer at an outermost part of the electrode assembly, and
said method includes the steps of: electrically insulating said casing from said positive electrode plate; and sticking said nail into the casing of said battery until it reaches the positive electrode active material layer positioned at the outermost part of said electrode assembly in said positive electrode plate.

6. The method for evaluating the safety of a battery under an internal short-circuit condition in accordance with claim 2,
wherein said casing is electrically connected to said positive electrode plate,
the electrode on the outermost side of said electrode assembly is said negative electrode plate,
said positive electrode plate has said positive electrode active material layer at an outermost part of the electrode assembly, and
said method includes the steps of: making a hole in said casing; and passing said nail through said hole in the casing and sticking said nail until it reaches the positive electrode active material layer positioned at the outermost part of said electrode assembly in said positive electrode plate.

7. The method for evaluating the safety of a battery under an internal short-circuit condition in accordance with claim 1, wherein a crushing member is pushed into said battery to deform said battery, thereby bringing said negative electrode plate into electrical contact with said positive electrode active material layer.

8. The method for evaluating the safety of a battery under an internal short-circuit condition in accordance with claim 7,
wherein said casing is electrically connected to said negative electrode plate,
the electrode on the outermost side of said electrode assembly is said negative electrode plate,
said positive electrode plate has an area where said positive electrode current collector is exposed at the outermost part of the electrode assembly, and
said method includes the steps of: cutting said area where said positive electrode current collector is exposed; and pushing said crushing member into said casing and said electrode assembly until the negative electrode plate positioned at the outermost part of said electrode assembly comes into contact with the positive electrode active material layer positioned at the outermost part of said electrode assembly in said positive electrode plate.

9. The method for evaluating the safety of a battery under an internal short-circuit condition in accordance with claim 7,
wherein said casing is electrically connected to said positive electrode plate,
the electrode on the outermost side of said electrode assembly is said negative electrode plate,
said positive electrode plate has said positive electrode active material layer at the outermost part of the electrode assembly, and
said method includes the steps of: electrically insulating said casing from said positive electrode plate; and pushing said crushing member into said casing and said electrode assembly until the negative electrode plate positioned at the outermost part of said electrode assembly comes into contact with the positive electrode active material layer positioned at the outermost part of said electrode assembly in said positive electrode.

10. The method for evaluating the safety of a battery under an internal short-circuit condition in accordance with claim 7,
wherein said casing is electrically connected to said positive electrode plate,
the electrode on the outermost side of said electrode assembly is said negative electrode plate,
said positive electrode plate has said positive electrode active material layer at the outermost part of the electrode assembly, and
said method includes the steps of: making a hole in said casing; and passing said crushing member through said hole in the casing and pushing said crushing member into said electrode assembly until the negative electrode plate positioned at the outermost part of said electrode assembly comes into contact with the positive electrode active material layer positioned at the outermost part of said electrode assembly in said positive electrode plate.

11. The method for evaluating the safety of a battery under an internal short-circuit condition in accordance with claim 1,
wherein a foreign object is placed between said positive electrode active material layer and said negative electrode plate in said electrode assembly, and
the part of said electrode assembly containing said foreign object is pressed by using a pressing member to bring said negative electrode plate into electrical contact with said positive electrode active material layer through said foreign object.

12. The method for evaluating the safety of a battery under an internal short-circuit condition in accordance with claim 1,
wherein said casing is electrically connected to said negative electrode plate,
the electrode on the outermost side of said electrode assembly is said negative electrode plate,
said positive electrode plate has an area where said positive electrode current collector is exposed at an outermost part of the electrode assembly, and
said method includes the steps of: removing said area where said positive electrode current collector is exposed; placing a foreign object between said positive electrode active material layer and said negative electrode plate in said electrode assembly; and pressing the part of said electrode assembly containing said foreign object by using a pressing member to bring said negative electrode plate into electrical contact with said positive electrode active material layer through said foreign object.

13. A battery the safety of which is identified by the safety evaluation method of claim 1.

14. A battery pack including a plurality of the batteries of claim 13.

15. A method for producing a battery, comprising the successive steps of:
(1) placing an electrode assembly in a casing, said electrode assembly comprising a wound laminate of a positive electrode plate, a negative electrode plate, and a separator interposed between said positive and negative electrode plates;
(2) injecting an electrolyte into said casing;
(3) sealing an opening of said casing with a sealing member to obtain a battery;
(4) subjecting the battery to an initial charge and aging; and
(5) identifying the safety of said battery under an internal short-circuit condition by the safety evaluation method of claim 1.

16. A method for producing a battery pack, comprising the step of placing a plurality of batteries obtained by the production method of claim 15 in a package.
